(19) United States
(12) Patent Application Publication
(10) Pub. No.: US 2016/0343722 A1
(43) Pub. Date: Nov. 24, 2016

(54) NONVOLATILE STORAGE WITH GAP IN INTER-GATE DIELECTRIC

(71) Applicant: SANDISK TECHNOLOGIES INC., Plano, TX (US)

(72) Inventors: Takashi Kashimura, Yokkaichi (JP); Sayako Nagamine, Yokkaichi (JP)

(73) Assignee: SANDISK TECHNOLOGIES INC., Plano, TX (US)

(21) Appl. No.: 14/718,746

(22) Filed: May 21, 2015

(51) Int. Cl. H01L 27/115; H01L 21/28; H01L 29/51

(52) U.S. Cl. CPC H01L 27/11521; H01L 29/513; H01L 21/28273

(57) ABSTRACT

A non-volatile memory device is provided that includes a gap in one of the layers of the inter-gate dielectric. One embodiment comprises a plurality of active areas, isolation regions between the active areas, a tunnel oxide layer above the active areas, a floating gate layer above the tunnel oxide layer, a control gate layer above the floating gate layer, and an inter-gate dielectric between the control gate layer and the floating gate layer. The inter-gate dielectric, which in one embodiment includes a SiN layer, is positioned above the isolation regions with gaps in the SiN layer over the isolation regions. Processes for manufacturing are also disclosed.

### BACKGROUND OF THE INVENTION

Semiconductor memory is widely used in various electronic devices such as cellular telephones, digital cameras, personal digital assistants, medical electronics, mobile computing devices, and non-mobile computing devices. Semiconductor memory may comprise non-volatile memory or volatile memory. A non-volatile memory allows information to be stored and retained even when the non-volatile memory is not connected to a source of power (e.g., a battery). Examples of non-volatile memory include flash memory (e.g., NAND-type and NOR-type flash memory) and Electrically Erasable Programmable Read-Only Memory (EEPROM).

Some non-volatile memory devices utilize a floating gate that is positioned above and insulated from a channel region in a semiconductor substrate. The floating gate is positioned between source and drain regions. A control gate is provided over the floating gate, and insulated from the floating gate by an inter-gate dielectric (also called an inter-poly dielectric) positioned between the control gate and the floating gate. The threshold voltage of the transistor is controlled by the amount of charge that is retained on the floating gate. That is, the minimum amount of voltage that must be applied to the control gate before the transistor is turned on to permit conduction between its source and drain is controlled by the level of charge on the floating gate.

As device sizes scale down, the inter-gate dielectric is important for non-volatile memory devices because the inter-gate dielectric effects the performance and reliability of the non-volatile memory devices. For example, the inter-gate dielectric can have an effect on the coupling ratio between the control gate and the floating gate. The inter-gate dielectric also effects data retention, which is the ability to maintain the correct data over time. For example, if the inter-gate dielectric allows charge to leak, then data can be lost.

### BRIEF DESCRIPTION OF THE DRAWINGS

FIG. 1 is a top view of a NAND string.

FIG. 2 is an equivalent circuit diagram of the NAND string.

FIG. 3 is a block diagram of a non-volatile memory system.

FIG. 4 depicts an exemplary structure of a memory cell array.

FIG. 5 depicts a cross section of a non-volatile memory device.

FIG. 6 depicts a cross section of a non-volatile memory device.

FIG. 7 depicts a cross section of a non-volatile memory device.

FIG. 8 is a flow chart of one embodiment of a process for fabricating the structure of FIG. 6.

FIGS. 9A-F are cross sections of the non-volatile memory device of FIG. 7 during various phases of fabrication.

FIG. 10 is a flow chart of one embodiment of a process for fabricating the structure of FIG. 7.

FIGS. 11A-D are cross sections of the non-volatile memory device of FIG. 7 during various phases of fabrication.

### DETAILED DESCRIPTION

A non-volatile memory device is provided that includes a gap in one of the layers of the inter-gate dielectric. For example, one embodiment includes a non-volatile memory device that comprises a first floating gate, a second floating gate, an isolation region positioned in a space between the first floating gate and the second floating gate, a control gate layer positioned over the first floating gate and the second floating gate, and an inter-gate dielectric positioned between the control gate layer and the first floating gate and between the control gate layer and the second floating gate. The inter-gate dielectric includes multiple layers. Additionally, the inter-gate dielectric is positioned above the isolation region with a gap in at least one layer of the inter-gate dielectric over the isolation region.

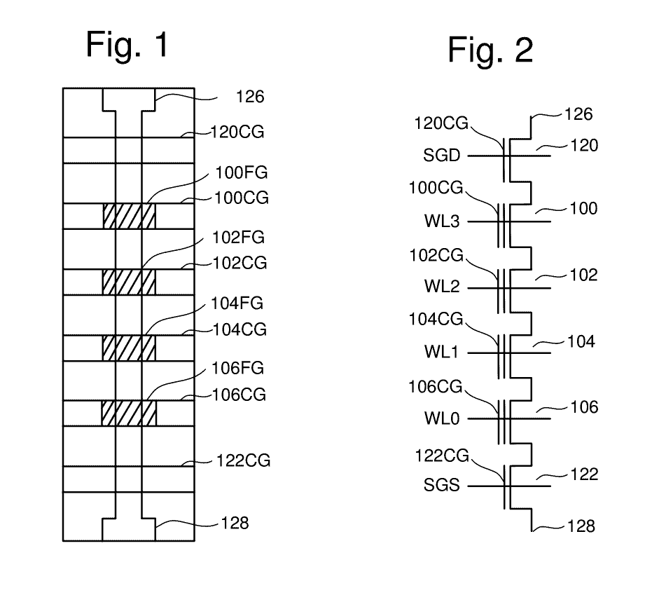

One example of a non-volatile storage system that can implement the technology described herein is a flash memory system that uses the NAND structure, which includes arranging multiple transistors in series, sandwiched between two select gates. The transistors in series and the select gates are referred to as a NAND string. FIG. 1 is a top view showing one NAND string. FIG. 2 is an equivalent circuit thereof. The NAND string depicted in FIGS. 1 and 2 includes four transistors 100, 102, 104 and 106 in series and sandwiched between (drain side) select gate 120 and (source side) select gate 122. Select gate 120 connects the NAND string to a bit line via bit line contact 126. Select gate 122 connects the NAND string to source line 128. Select gate 120 is controlled by applying the appropriate voltages to select line SGD. Select gate 122 is controlled by applying the appropriate voltages to select line SGS. Each of the transistors 100, 102, 104 and 106 has a control gate and a floating gate. For example, transistor 100 has control gate 100CG and floating gate 100FG. Transistor 102 includes control gate 102CG and a floating gate 102FG. Transistor 104 includes control gate 104CG and floating gate 104FG. Transistor 106 includes a control gate 106CG and a floating gate 106FG. Control gate 100CG is connected to word line WL3, control gate 102CG is connected to word line WL2, control gate 104CG is connected to word line WL1, and control gate 106CG is connected to word line WL0.

Note that although FIGS. 1 and 2 show four memory cells in the NAND string, the use of four memory cells is only provided as an example. A NAND string can have less than four memory cells or more than four memory cells. For example, some NAND strings will have 128 memory cells or more. The discussion herein is not limited to any particular number of memory cells in a NAND string. One embodiment uses NAND strings with 66 memory cells, where 64 memory cells are used to store data and two of the memory cells are referred to as dummy memory cells because they do not store data.

A typical architecture for a flash memory system using a NAND structure will include several NAND strings. Each NAND string is connected to the common source line by its source select gate controlled by select line SGS and connected to its associated bit line by its drain select gate controlled by select line SGD. Each bit line and the respective NAND string(s) that are connected to that bit line via a bit line contact comprise the columns of the array of memory cells. Bit lines are shared with multiple NAND strings. Typically, the bit line runs on top of the NAND strings in a direction perpendicular to the word lines and is connected to a sense amplifier.

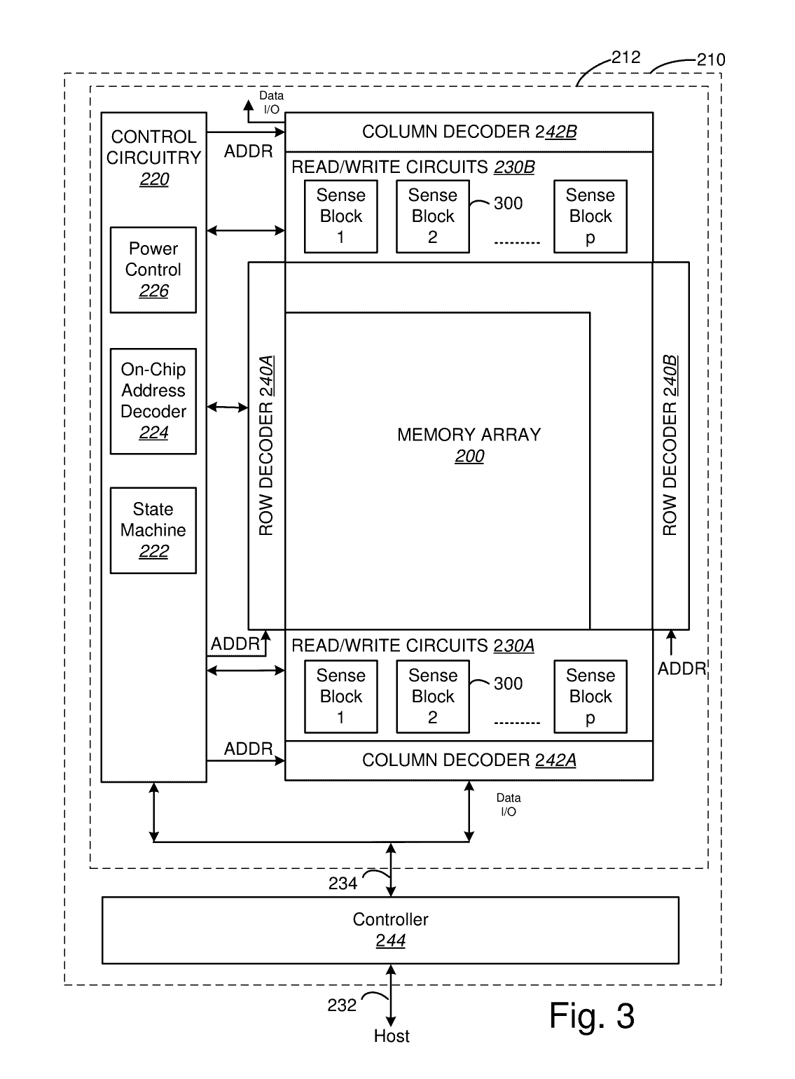

FIG. 3 illustrates a memory device 210 having read/write circuits for reading and programming a page of memory cells (e.g., NAND multi-state flash memory) in parallel. Memory device 210 may include one or more memory die or chips 212. Memory die 212 includes an array (two-dimensional or three dimensional) of memory cells 200, control circuitry 220, and read/write circuits 230A and 230B. In one embodiment, access to the memory array 200 by the various peripheral circuits is implemented in a symmetric fashion, on opposite sides of the array, so that the densities of access lines and circuitry on each side are reduced by half. The read/write circuits 230A and 230B include multiple sense blocks 300 which allow a page of memory cells to be read or programmed in parallel. The memory array 200 is addressable by word lines via row decoders 240A and 240B and by bit lines via column decoders 242A and 242B. In a typical embodiment, a controller 244 is included in the same memory device 210 (e.g., a removable storage card or package) as the one or more memory die 212. Commands and data are transferred between the host and controller 244 via lines 232 and between the controller and the one or more memory die 212 via lines 234. Some memory systems may include multiple dies 212 in communication with Controller 244.

Control circuitry 220 cooperates with the read/write circuits 230A and 230B to perform memory operations on the memory array 200. The control circuitry 220 includes a state machine 222, an on-chip address decoder 224 and a power control module 226. The state machine 222 provides chip-level control of memory operations. The on-chip address decoder 224 provides an address interface between that used by the host or a memory controller to the hardware address used by the decoders 240A, 240B, 242A, and 242B. The power control module 226 controls the power and voltages supplied to the word lines and bit lines during memory operations. In one embodiment, power control module 226 includes one or more charge pumps that can create voltages larger than the supply voltage. Control circuitry 220, power control 226, decoder 224, state machine 222, decoders 240 A/B & 242A/B, the read/write circuits 230A/B and the controller 244, collectively or separately, can be referred to as one or more managing circuits or one or more control circuits.

In one embodiment, the host is a computing device (e.g., laptop, desktop, smartphone, tablet, digital camera, etc.) that includes one or more processors, one or more processor readable storage devices (RAM, ROM, flash memory, hard disk drive, etc.) that store processor readable code (e.g., software) for programming the one or more processors to perform the methods described herein. The host may also include additional system memory, one or more input/output interfaces and/or one or more input/output devices in communication with the one or more processors.

In one embodiment, state machine 222 may be fully implemented in hardware. In another embodiment, state machine 222 may be implemented in a combination of hardware and software. For example, state machine 222 may include one or more processors and one or more processor readable storage devices (RAM, ROM, flash memory, hard disk drive, etc.) that store processor readable code (e.g., software) for programming the one or more processors to perform the methods described herein.

In one embodiment, controller 244 may be fully implemented in hardware. In another embodiment, controller 244 may be implemented in a combination of hardware and software. For example, controller 244 may include one or more processors and one or more processor readable storage devices (RAM, ROM, flash memory, hard disk drive, etc.) that store processor readable code (e.g., software) for programming the one or more processors to perform the methods described herein.

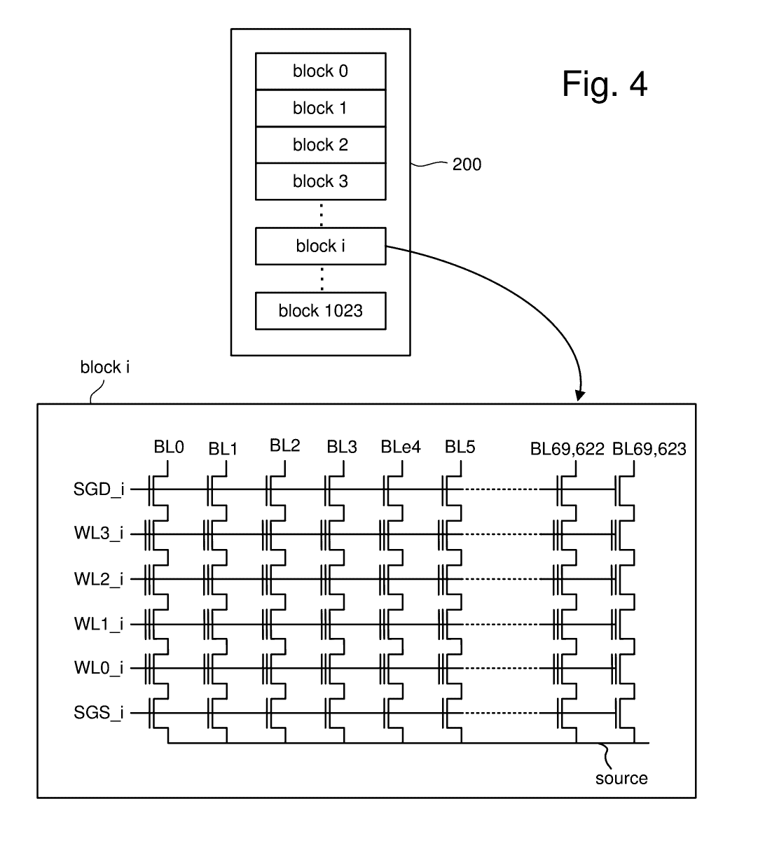

FIG. 4 depicts an exemplary structure of memory cell array 200. In one embodiment, the array of memory cells is divided into a large number of blocks of memory cells. As is common for flash EEPROM systems, the block is the unit of erase. That is, each block contains the minimum number of memory cells that are erased together. Other embodiments can use different units of erase.

As one example, the NAND flash EEPROM depicted in FIG. 4 is partitioned into 1,024 blocks. However, more or less than 1024 blocks can be used. In each block, in this example, there are 69,624 columns corresponding to bit lines BL0, BL1, BL69,623. In one embodiment, all of the bit lines of a block can be simultaneously selected during read and program operations. Memory cells along a common word line and connected to any bit line can be programmed (or read) at the same time (e.g., concurrently

FIG. 4 shows four memory cells connected in series to form a NAND string. Although four cells are shown to be included in each NAND string, more or less than four can be used (e.g., 16, 32, 64, 128 or another number or memory cells can be on a NAND string). One terminal of the NAND string is connected to a corresponding bit line via a drain select gate (connected to select gate drain line SGD), and another terminal is connected to the source line via a source select gate (connected to select gate source line SGS).

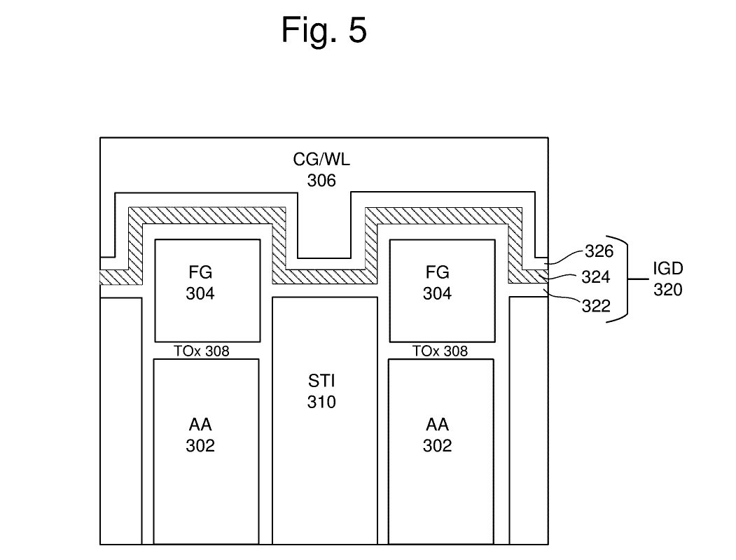

FIG. 5 depicts a cross section of a non-volatile memory device, showing two NAND strings. Two active areas 302 are depicted. Each active area 302 represents a portion (e.g. p-well) of the substrate for which a NAND string is built upon. The top surface of the active area 302 is used to implement the channel for the NAND string. Active areas 302 are electrically isolated from each other by shallow trench isolation regions 310, which are positioned between the active regions 302. It can also be said that shallow trench isolation regions 310 are positioned in the space between the floating gates 304. Above each active area 302 is the respective floating gate 304. Above the depicted floating gates 304 is a control gate/word line 306. In one embodiment, the control gate is also the word line. In other embodiments, the control gate and word line can be separate structures. In the embodiment of FIG. 5, one control gate or word line connects one memory cell in each NAND string of the block. One control gate or word line will be positioned above one floating gate in each NAND string of the block. For example, control gate/word line 306 is positioned over both floating gates 304 depicted in FIG. 5. Between floating gates 304 and active areas 302 are tunnel oxide regions 308. In one embodiment, the tunnel oxide region 308 comprises SiO₂.

Between the floating gates 304 and control gate 306 is inter-gate dielectric 320. It one embodiment, inter-gate dielectric 320 includes three layers 322, 324 and 326. In one embodiment, the inter-gate dielectric 320 comprises an ONO structure made up of an oxide layer, a nitride layer, and an oxide layer. For example, layer 322 is a lower oxide layer, layer 324 is an inner nitride layer, and layer 326 is an upper oxide layer 326. In one embodiment, oxide layers 322 and 326 comprise SiO₂; however, other compositions can be used. In one embodiment, nitride layer 324 is a silicon nitride layer, comprising SiN. Other compositions can also be implemented. One purpose of inter-gate dielectric 320 is to insulate the floating gates 304 from control gates 306 so that no charge can leak between the floating gate 304 and control gate 306. Inter-gate dielectric 320 also has an effect on the capacitive coupling ratio between control gates 306 and floating gates 304.

In one embodiment, programming the memory cells includes electrons tunneling from the channel in active area 302 into a floating gate 304, through tunnel oxide 308. Erasing is performed by electrons tunneling from one or more of the floating gates 304 back into active area 302 via tunnel oxide 308.

As can be seen from FIG. 5, it is typical that the three layers of the inter-gate dielectric will surround the portion of the floating gates 304 and further be positioned over the shallow trench isolation regions 310. It is important that the inter-gate dielectric 320 prevent charge from leaking out of the floating gate 304 into the control gate 306 or into adjacent floating gates 304. Similarly, inter-gate dielectric 320 should also prevent charge from leaking into floating gate 304 from control gate 306 or an adjacent floating gate. If electrons are allowed to leak into or out of a floating gate 304, data could be lost. The ability to retain data is known as “data retention.”

It has been observed, that after many program erase cycles, some non-volatile memory devices will experience electrons leaking out of respective floating gates, therefore, causing data retention problems. One path for electrons leaking out of a floating gate is to a neighboring floating gate. To suppress such electron leakage, it is proposed to create a new inter-gate dielectric structure that includes a gap in one of the layers of the inter-gate dielectric over the shallow trench isolation region 310. In one embodiment, it is the nitride layer (or SiN layer) that will include the gap over the shallow trench isolation region 310. In other embodiments, other layers can include a gap.

Previous approaches to suppress electron leakage to neighboring floating gates through an inter-gate dielectric included thinning the SiN layer. There are two ways for thinning the SiN layer. In the first example, the SiN layer can be thinned in a manner that keeps the total physical thickness of the inter-gate dielectric the same by thickening the oxide layers. In the second example, the effective oxide thickness of the inter-gate dielectric can be kept constant by adjusting the physical thickness of the oxide layer. The first example can be effective a reducing electron leakage to neighboring floating gates; however, program disturb can be an issue because of a degradation in the coupling ratios due to the increase in effective oxide thickness of the inter-gate dielectric. The second example may also be effective at reducing electron leakage to neighboring floating gates; however, it makes total physical thickness of the inter-gate dielectric thinner which allows electrons to leak from the floating gate to the control gate. Therefore, data retention may actually get worse. The new proposal to suppress electron leakage through a gap in the nitride layer of the inter-gate dielectric is effective at reducing electron leakage to neighboring floating gates without increasing program disturb or increasing any leakage to the control gate.

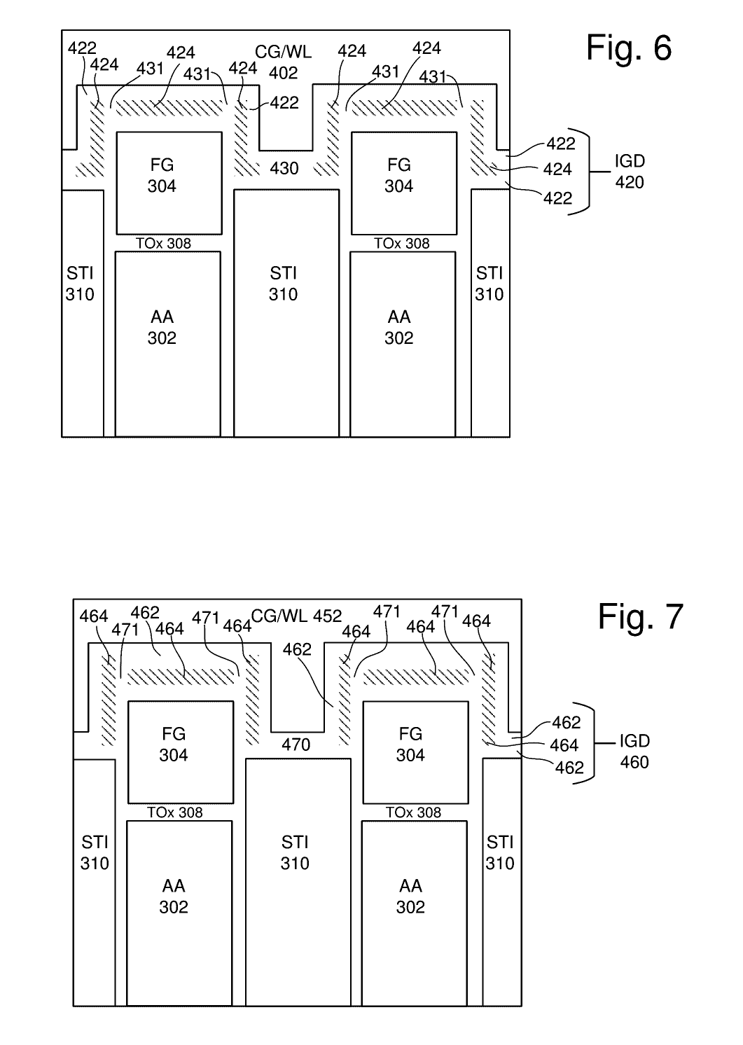

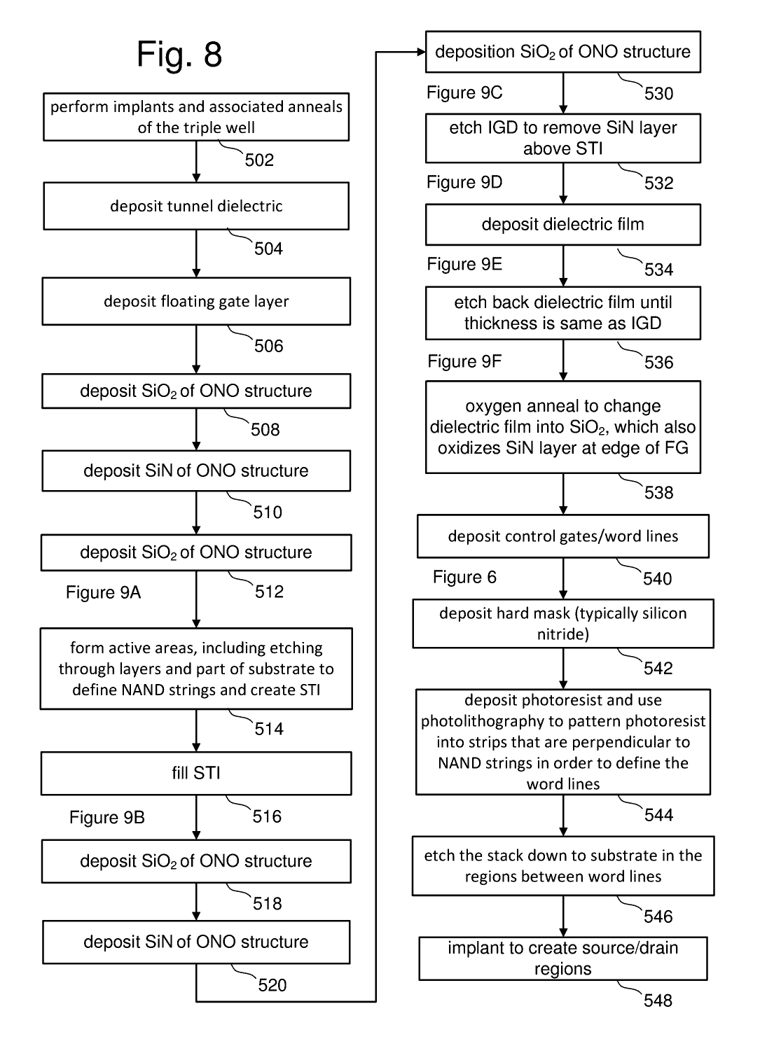

FIGS. 6 and 7 depict two embodiments of structures of a non-volatile memory device that includes a gap in one of the layers of the inter-gate dielectric. The first embodiment, depicted in FIG. 6, includes the same active areas 302, floating gates 304, tunnel oxides 308 and shallow trench isolation regions 310 as the structure in FIG. 5. Note that the shallow trench isolation region 310 can also be referred to as an isolation region. In some embodiments, the isolation region need not be a shallow trench. The structure in FIG. 6 also includes a control gate/word line 402 which may or may not be the same shape and structure as control gate/word line 306 in FIG. 5. As in FIG. 5, FIG. 6 shows a cross section across two NAND strings. One NAND string is implemented on one of the active regions 302 and another NAND string is implemented on the other active region 302, with the active areas 302 providing the channels for the NAND strings.

Between control gate/word line 402 and the floating gates 304 is an inter-gate dielectric 420. In one embodiment, inter-gate dielectric 420 includes three layers that comprise an ONO structure. The three layers include two outer oxide layers 422 and an inner/middle nitride layer 424. In one embodiment, the outer oxide layers 422 comprise SiO₂; however, in other embodiments, other dielectric materials could also be used. Inner/middle nitride layer 424 comprises SiN; however, other chemical compositions can also be used. As can be seen in FIG. 5, inner/middle layer 424 (the SiN layer) includes a gap 430 above isolation region 310. In one embodiment, in the portion of inter-gate dielectric 420 comprising gap 430, the SiN is replaced with SiO₂. This structure can suppress leakage through the SiN layer in the inter-gate dielectric, leading to an improvement of data retention. In the structure of FIG. 6, gap 430 is narrower than the width of isolation region 310. Additionally, a portion of the inner/middle layer 424 still remains above isolation region 310. Inter-gate dielectric 420 includes a region that surrounds a portion of floating gates 304, and these regions include additional gaps 431 in the middle/inner layer 424 (e.g., SiN layer).

FIG. 7 provides another embodiment of a structure of a memory device that includes a gap in one of the layers of the inter-gate dielectric. The structure show in cross section in FIG. 7 includes the same active areas 302, floating gates 304, tunnel oxide 308 and isolation region 310 of FIGS. 5 and 6. Additionally, FIG. 7 shows a control gate/word line 452 above floating gates 304. Between control gate/word line 452 and floating gates 304 is inter-gate dielectric 460. In one embodiment, inter-gate dielectric 460 implements an ONO structure with three layers (oxide layer, nitride layer, oxide layer). Outer layers 462 are oxide layers. Inner/middle layer 464 is a nitride layer. As can be seen, there is a gap 470 in inner/middle layer 464 (e.g., the SiN layer). Gap 470 is over isolation region 310. Note that gap 470 of FIG. 7 is much larger than gap 430 of FIG. 6. Gap 470 of FIG. 7 is almost big enough such than none of the inner/middle layer (i.e. SiN layer) is positioned over any portion of the isolation region. However, in one embodiment, the gap can be sized so that the inner/middle layer 464 is not positioned over any portion of the isolation region. Inter-gate dielectric 460 includes regions that surround a portion of the floating gates 304. Those regions surrounding portions of the floating gates include a top wall and two side walls, where the two side walls extend higher than the top surface of the top wall, as depicted in FIG. 7. Those regions surrounding portions of the floating gates include additional gaps 471 between the side walls and top wall of middle/inner layer 464 (SiN layer).

FIG. 8 is a flow chart describing one embodiment of the front end of a process for manufacturing the memory structure of FIG. 6, which covers processed steps only as far as implanting the source/drain regions. To manufacture a complete memory structure, additional steps would be needed, which are known in the art. There are many ways to manufacturer memory according to the proposed structures and, thus, it is contemplated that various methods other than that described by FIG. 8 can be used. Typically, a flash memory die will consist of both a peripheral circuitry which includes a variety of low, medium, and high voltage transistors and the core memory array. The process steps of FIG. 8 are intended only to describe in general terms one possible process recipe for the fabrication of a portion of the core memory array. Many photolithography, etch, implant, diffusion and oxidation steps that are known in the art and intended for the fabrication of the peripheral transistors are omitted.

Step 502 of FIG. 8 includes performing implants and associated anneals of the triple well. The results of step 502 includes a P-substrate, an N-well within the P-substrate, and a P-well within the N-well. The sidewalls of the N-well isolate the P-wells from another. In one embodiment, active areas 302 are part of the P-well. In step 504, a tunnel dielectric layer (e.g., SiO₂) is deposited on top of the active area 302 (e.g., on top of the P-well). The tunnel dielectric can be deposited using Chemical Vapor Deposition (CVD), Metal Organic CVD (MOCVD), Physical Vapor Deposition (PVD), Atomic Layer Deposition (ALD), or another suitable method. Additionally (and optionally), other materials may deposited it on, deposited under or incorporated within the tunnel dielectric. In step 406, a floating gate layer is deposited over the tunnel dielectric layer using CVD, PVD, ALD or another suitable method. Steps 508, 510 and 512 include adding an ONO structure. In step 508, a first oxide layer (e.g., SiO₂) of the ONO structure is deposited on top of the floating gate layer using CVD, PVD, ALD or another suitable method. In step 510, a nitride layer (e.g., SiN) of the ONO structure is deposited on top of the oxide layer using CVD, PVD, ALD or another suitable method. In step 512, a top oxide layer is deposited on top of the nitride layer using CVD, PVD, ALD or another suitable method. The result of steps 502-512 are depicted in FIG. 10(A), which shows active area 302, tunnel oxide 308, floating gate 304, oxide layer 422, nitride layer 424, and oxide layer 422.

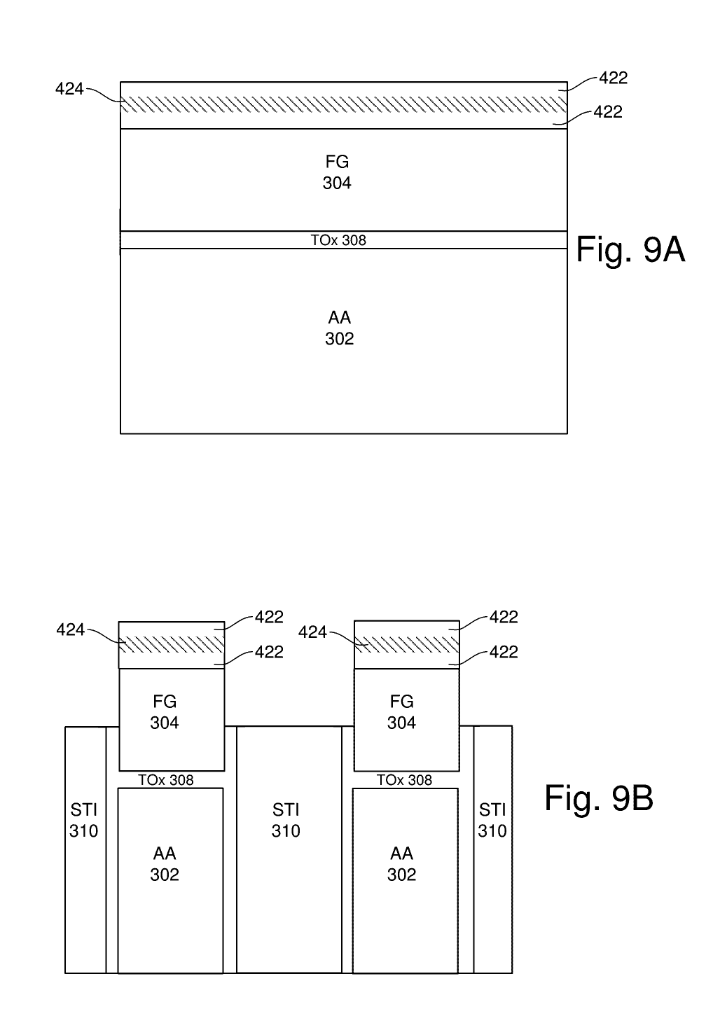

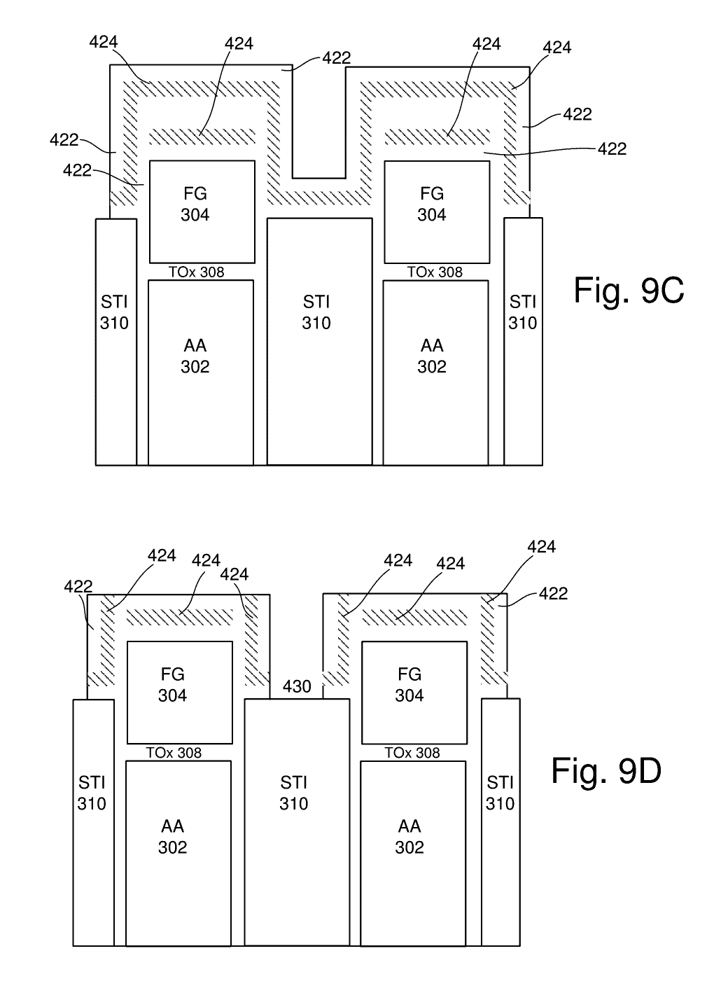

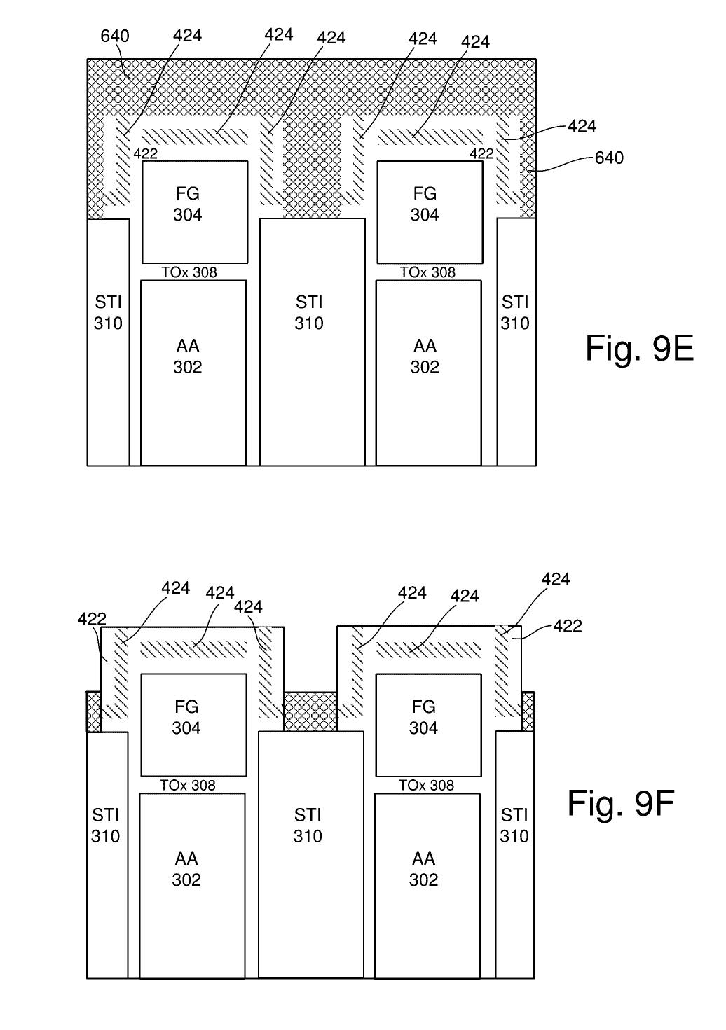

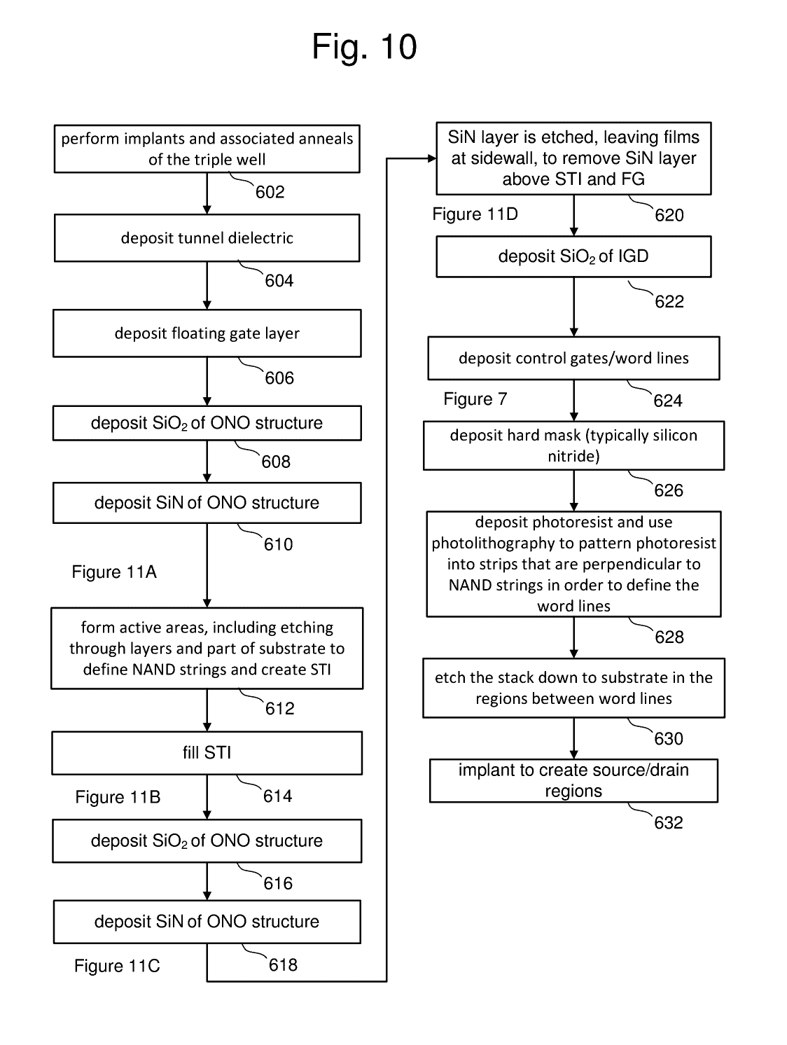

In step 514, the active areas are formed from the structure of FIG. 9(A) by etching through the various layers depicted in FIG. 9(A) to define NAND strings and create the shallow trench isolation regions 310. One embodiment includes depositing a hard mask, for example CVD to deposit Si₃N₄. Then, photolithography is used to form strips of photoresist of what will become the NAND strings in etchings performed through all the layers, including part of the substrate. First the hard mask is etched through using anisotropic plasma etching (i.e., reactive ion etching) with proper balance between physical and chemical etching for plane or layer encountered. After the hard mask layer is etched into strips, the photo resist can be stripped away and the hard mask layer can be used as the mask for etching the underlying layers. The process then includes etching through the floating gate material, tunnel oxide and a portion of the substrate to create the trenches. Other known techniques for creating the active areas can also be used.

In step 516, the shallow trench isolation regions 310 are filled with SiO₂ (or another suitable material) using CVD, rapid ALD or other process. In other embodiments, a PSZ STI fill can be used. The result of Step 516 is depicted in FIG. 9(B), which shows the active areas 302 properly formed and isolation region 310 in the spaces between floating gates 304. Additionally, oxide layers 422 and nitride layer 424 have been patterned to include only strips above floating gate 304.

In step 518, an oxide layer (e.g. SiO₂) is deposited. This oxide layer is the lower layer of an ONO structure. In step 520, a nitride layer (e.g., SiN) is deposited on top of the oxide layer of step 518. In step 530, a top oxide layer is deposited on top of the nitride layer of Step 520. Steps 518, 520 and 530 deposit a second ONO structure (with the first ONO structure deposited in steps 508, 510 and 512). The result of step 530 is depicted in FIG. 9(C), which shows three oxide layers 422 and two nitride layers 424 positioned over floating gates 304. At this point in the process of FIG. 8, a first ONO structure was added on top of the floating gate and then a second ONO structure was added on top of the first ONO structure in order to create a ONONO structure above the floating gate, while a single ONO structure is above isolation region 310.

In step 532, an etching process is performed on inter-gate dielectric 420 to remove a portion of the nitride layer 424 above isolation region 310. This etching process also removes the top layer of the nitride layer above floating gate 304 and a top layer of oxide above floating gate 304. The result of the etching process of step 532 is depicted in FIG. 9(D). Since the nitride layer 422 was removed from above isolation region 310, gap 430 now exists in nitride layer 424. Additionally, there is only one nitride layer 424 above each of the floating gates 304.

In step 534, a dielectric film is deposited on to the structure of FIG. 9(D) in order to fill in any openings/gaps, etc. In one embodiment, a high quality dielectric film in a liquid-like state is deposited on the wafer surface, allowing the film to flow into any gaps or crevices and fill in without voids or seams. One example of a suitable film is ETERNA FCVD from Applied Materials. The results of step 534 are depicted in FIG. 9(E), which shows film 640 filling in empty spaces. In step 536, the film deposited in step 534 is etched back until it is the same thickness as the inter-gate dielectric, as depicted in FIG. 9(F). In step 538, an oxygen anneal is performed to change the dielectric film into SiO₂. In step 540, control gates/word lines are deposited according to techniques known in the art. The result of step 540 is depicted in FIG. 6. In step 542, hard masks are deposited (typically silicon nitrate). In step 544, photoresist is deposited and photolithography is used to pattern the photoresist into strips that are perpendicular to NAND strings in order to define the word lines. In step 546, the stacks are etched down to the substrate (ie active area) in the regions between word lines. In step 548, implants are performed to create source/drain regions for the NAND strings.

Note that Step 532 removes a portion of the SiN layer to create the gap above the isolation region and step 538 completes the filling in of that gap with SiO₂. Additionally, as described above, the process of FIG. 8 includes adding multiple ONO layers and partially etching of the ONO layers, including creating the gap. In one embodiment, the first ONO layer was added in steps 508-512 and the second ONO layer is added In steps 518-530, with the etching of the second ONO layer being the final step in creating the gap in the SiN layer.

FIG. 10 is a flow chart describing another embodiment of the front end of a process for manufacturing the memory structure of FIG. 7, which covers processed steps only as far as implanting the source/drain regions. This process flow does not cover all the steps to manufacture a memory system. Many additional steps known in the art also needed to be performed to manufacture a memory system. The process in FIG. 10 includes adding two nitride layers and three oxide layers, in order to form one nitride layer between the two oxide layers above the floating gate and one oxide layer above the isolation regions.

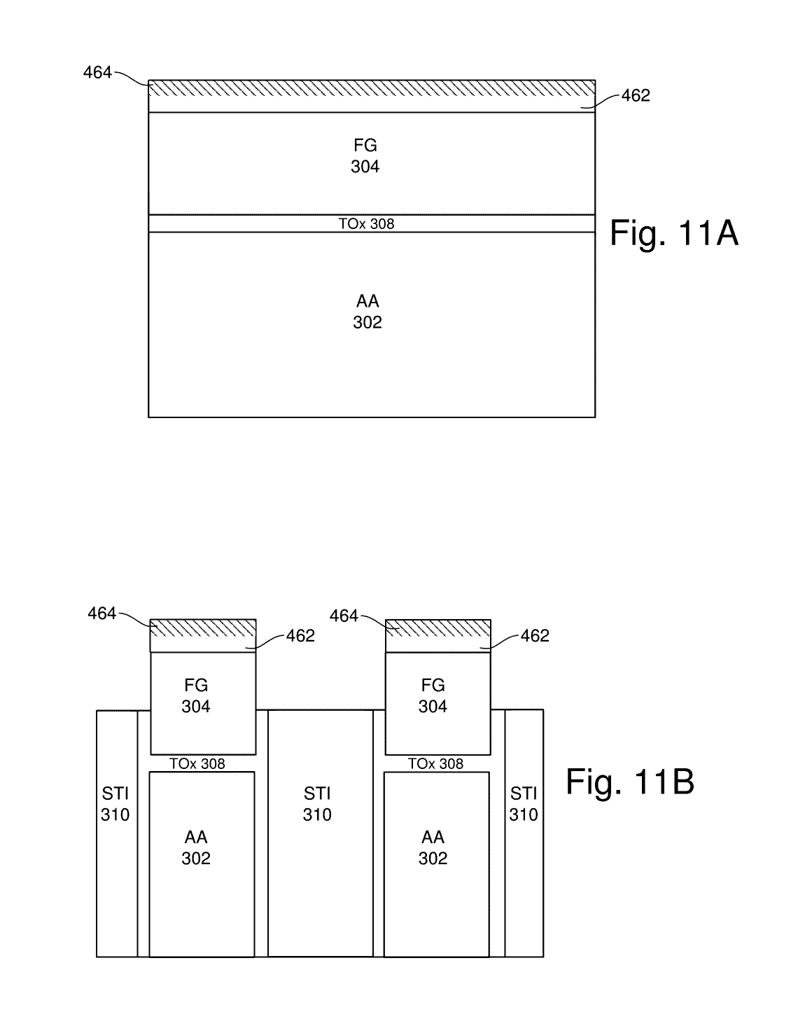

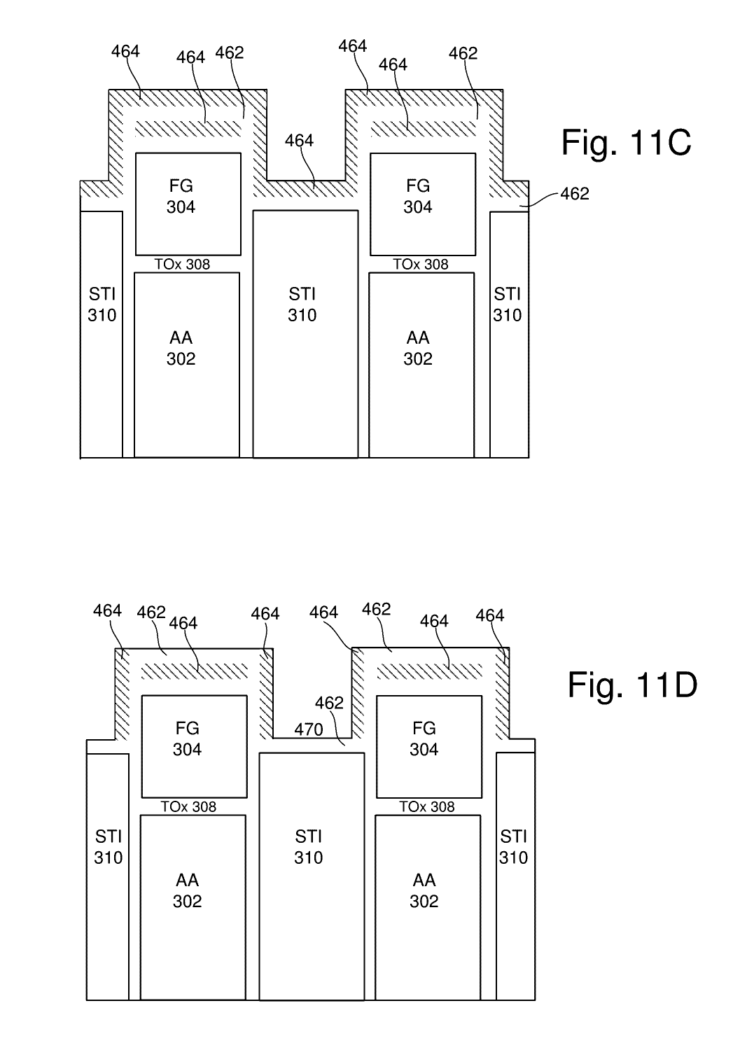

Step 602 of FIG. 10 includes performing the implants and associated anneals to create the triple well, and is the same process as step 502 of FIG. 8. Step 604 of FIG. 10 includes depositing the tunnel dielectric, as in step 504 of FIG. 8. Step 606 includes depositing the floating gate layer, as in step 506 of FIG. 8. Step 608 includes depositing an oxide layer (e.g., SiO₂) of an ONO structure using CVD, PVD, ALD or another suitable method. Step 610 includes depositing a nitride layer (e.g., SiN) of an ONO structure using CVD, PVD, ALD or another suitable method. The results of Steps 602-610 are depicted in FIG. 11(A), which shows nitride layer 464 over oxide layer 462, which is on top of floating gate 304. The layer for floating gate 304 is on top of the layer for tunnel oxide 308, which sits on top of the layer for active area 302.

Step 612 of FIG. 10 includes forming the active area, including etching through layers in part of the substrate to define the NAND strings and create the isolation regions. Step 612 of FIG. 10 is similar to step 514 in FIG. 8. Note that in step 612, when etching to create the active areas and isolation region, the process etches through the first oxide layer deposited in step 608 and the first nitride layer deposit deposited in step 610.

Step 614 includes filling this shallow trench isolation region, in the same manner as discussed above with respect to step 516 of FIG. 8. The result of step 614 is depicted in FIG. 11(B) which shows active areas 302 and isolation region 310 being defined. Additionally, floating gates 304 are defined, with strips of oxide layer 462 and nitride layer 464 positioned over the floating gates 304.

In step 616, an oxide layer (e.g., SiO₂) of an ONO structure is deposited using CVD, PVD, ALD or another suitable method. In step 618, a nitride layer (e.g., SiN) of an ONO structure is deposited using CVD, PVD, ALD or another suitable method. The results of step 618 are depicted in FIG. 11(C). As can be seen, at this point in the process, there are two nitride layers 464 and two oxide layers 462 over each of the floating gates 304, with only one nitride layer 464 and one oxide layer 462 positioned over isolation regions 310.

In step 620, the top nitride (e.g., SiN) layer is etched, leaving films at the sidewall, in order to remove the nitride layer (e.g., SiN) above the isolation region 310 and floating gates 304. The results of Step 620 are depicted in FIG. 11(D). As can been seen, gap 470 has been formed in nitride layer 464 over isolation region 310. In step 622, an oxide layer is deposited using CVD, PVD, ALD or another suitable method. In step 624, control gates/word lines are deposited. The results of Step 624 are depicted in FIG. 7.

In step 626, hard mask is deposited (typically of silicon nitrate). Photoresist is deposited in step 628 and used with photolithography to pattern the photoresist into strips that are perpendicular to the NAND strings in order to define the word lines. In step 630, the stack is etched down to the substrate in the regions between the word lines. In step 632, an implant process is performed to create source drain regions in the substrate (P-well of active area).

One embodiment includes a non-volatile memory device, comprising: a first floating gate; a second floating gate; an isolation region positioned in a space between the first floating gate and the second floating gate; a control gate layer positioned over the first floating gate and the second floating gate; and an inter-gate dielectric comprising multiple layers that are positioned between the control gate layer and the first floating gate and between the control gate layer and the second floating gate, the inter-gate dielectric is positioned above the isolation region with a gap in at least one layer of the inter-gate dielectric over the isolation region.

One embodiment includes a non-volatile memory device, comprising: a plurality of active areas for NAND strings; shallow trench isolation regions between the active areas; a tunnel oxide layer above the active areas; a floating gate layer above the tunnel oxide layer; a control gate layer above the floating gate layer; and an inter-gate dielectric between the control gate layer and the floating gate layer, the inter-gate dielectric includes a SiN layer, the inter-gate dielectric is positioned above the shallow trench isolation regions with gaps in the SiN layer over the shallow trench isolation regions.

One embodiment includes a method for fabricating non-volatile memory, comprising: adding a floating gate layer; creating an isolation region; adding an inter-gate dielectric that is positioned above the floating gate layer and above the isolation region, the inter-gate dielectric includes an SiN layer, the adding an inter-gate dielectric includes positioning the SiN layer above the isolation region and then removing a portion of the SIN layer to create a gap in the SiN layer above the isolation region; and adding a control gate layer above the inter-gate dielectric.

In one example implementation, the adding an inter-gate dielectric comprises: adding a first ONO layer on top of the floating gate layer; etching through a portion of the first ONO layer when creating the isolation region; adding a second ONO layer on top of the first ONO layer to create a ONONO structure above the floating gate layer and an ONO structure above the isolation region; and etching a portion of the second ONO layer including creating the gap, the SiN layer includes the second ONO layer.

In one example implementation, the adding an inter-gate dielectric comprises: adding a first oxide layer on top of the floating gate layer; adding a first nitride layer on top of the first oxide layer; etching through the first oxide layer and the first nitride layer when creating the isolation region; adding a second oxide layer on top of what remains of the first nitride layer and on top of the isolation region; adding a second nitride layer on top of the second oxide layer, the SiN layer includes the second nitride layer; etching the second nitride layer to remove portions of second nitride layer above the isolation region, including creating the gap; and adding a third oxide layer above the floating gate layer and above the isolation region.

One embodiment includes a method for fabricating non-volatile memory, comprising: adding a floating gate layer; creating an isolation region between active areas; adding a multi-layer inter-gate dielectric above the floating gate layer and above the isolation region with a gap in one of the layers of the inter-gate dielectric above the isolation region; and adding a control gate layer above the inter-gate dielectric.

For purposes of this document, it should be noted that the dimensions of the various features depicted in the figures may not necessarily be drawn to scale.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via another part). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication: if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

For purposes of this document, directional terms such above, below, on top of, etc. are in reference to the substrate. Therefore, turning/rotating the entire device does not change the directional relations discussed herein.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles and practical application of the proposed technology, to thereby enable others skilled in the art to best utilize the technology in various embodiments and with various modifications as are suited to the particular use contemplated. It is intended that the scope be defined by the claims appended hereto.

1. A non-volatile memory device, comprising:
a first floating gate;
a second floating gate;
an isolation region positioned in a space between the first floating gate and the second floating gate;
a control gate layer positioned over the first floating gate and the second floating gate; and
an inter-gate dielectric comprising multiple layers that are positioned between the control gate layer and the first floating gate and between the control gate layer and the second floating gate, the inter-gate dielectric contacts and is positioned along a top surface of the first floating gate and a top surface of the second floating gate, the inter-gate dielectric is positioned above the isolation region with a gap in at least one layer of the inter-gate dielectric over the isolation region.

2. The non-volatile memory device of claim 1, wherein:
the multiple layers of the inter-gate dielectric include a nitride layer; and
the inter-gate dielectric is positioned above the isolation region with the gap over the isolation region being in the nitride layer.

3. The non-volatile memory device of claim 1, wherein:
the multiple layers of the inter-gate dielectric include a silicon nitride layer; and
the inter-gate dielectric is positioned above the isolation region with the gap over the isolation region being in the silicon nitride layer.

4. The non-volatile memory device of claim 1, wherein:
inter-gate dielectric is an ONO structure with an inner N layer and outer O layers; and
the inter-gate dielectric is positioned above the isolation region with the gap over the isolation region being in the inner N layer.

5. The non-volatile memory device of claim 4, wherein:
the inter-gate dielectric includes a region surrounding a portion of the first floating gate;
and in the region surrounding the portion of the first floating gate the inner N layer has a top wall and two side walls, the two side walls extend higher than the top wall.

6. A non-volatile memory device, comprising:
a first floating gate;
a second floating gate;
an isolation region positioned in a space between the first floating gate and the second floating gate;
a control gate layer positioned over the first floating gate and the second floating gate; and
an inter-gate dielectric comprising multiple layers that are positioned between the control gate layer and the first floating gate and between the control gate layer and the second floating gate, the inter-gate dielectric is positioned above the isolation region with a gap in at least one layer of the inter-gate dielectric over the isolation region, the inter-gate dielectric is an ONO structure with an inner N layer and outer O layers, the inter-gate dielectric is positioned above the isolation region with the gap over the isolation region being in the inner N layer, the inter-gate dielectric includes a region surrounding a portion of the first floating gate, in the region surrounding the portion of the first floating gate the inner N layer has a top wall and two side walls, the two side walls extend higher than the top wall, the gap is sized such that the inner N layer is not positioned over any portion of the isolation region.

7. The non-volatile memory device of claim 4, wherein:
a portion of the inner N layer is positioned above the isolation region.

8. The non-volatile memory device of claim 1, wherein:
the gap is narrower than a width of the isolation region.

9. The non-volatile memory device of claim 1, wherein:
inter-gate dielectric includes an ONO structure with an inner SiN layer and outer SiO₂ layers; and
the inter-gate dielectric is positioned above the isolation region with the gap over the isolation region being in the SiN layer.

10. The non-volatile memory device of claim 1, wherein:
the inter-gate dielectric includes an inner layer between two outer layers; and
the inter-gate dielectric is positioned above the isolation region with the gap over the isolation region being in the inner layer;
the inter-gate dielectric includes a region surrounding a portion of the first floating gate;
in the region surrounding the portion of the first floating gate the inner layer has a top wall and two side walls; and
the inner layer includes additional gaps between the top wall and the two side walls.

11. The non-volatile memory device of claim 1, wherein:
the inter-gate dielectric includes a region surrounding a portion of the first floating gate; and
the inter-gate dielectric includes additional gaps in the one the layer of the inter-gate dielectric in the region surrounding the portion of the first floating gate.

12. The non-volatile memory device of claim 1, further comprising:
a first active area positioned under the first floating gate, the first active area serves as a channel for the first floating gate;
a first tunnel dielectric region between the first active area and the first floating gate;
a second active area positioned under the second floating gate, the second active area serves as a channel for the second floating gate, the isolation region is positioned between the first active area and the second active area; and
a second tunnel dielectric region between the second active area and the second floating gate.

13. A non-volatile memory device, comprising:
a plurality of active areas for NAND strings;
shallow trench isolation regions between the active areas;
a tunnel oxide layer above the active areas;
a floating gate layer above the tunnel oxide layer;
a control gate layer above the floating gate layer; and
an inter-gate dielectric between the control gate layer and the floating gate layer, the inter-gate dielectric includes an inner layer between two outer layers, the inter-gate dielectric is positioned above the shallow trench isolation regions with gaps in the inner layer over the shallow trench isolation regions, the two outer layers completely cross the shallow trench isolation regions between adjacent active areas.

14. The non-volatile memory device of claim 13, wherein:
the inter-gate dielectric includes an ONO structure with the inner layer comprising a SiN layer and the two outer layers are oxide layers, the oxide layers do not include gaps.

15. The non-volatile memory device of claim 13, wherein:
the inter-gate dielectric layer contacts a top surface of the floating gate layer; and
the inter-gate dielectric layer includes additional gaps in the regions that partially surround the floating gate layer.

16-24. (canceled)

25. The non-volatile memory device of claim 13, wherein:
the inter-gate dielectric layer contacts a top surface of the floating gate layer.

26. The non-volatile memory device of claim 13, wherein:
the inter-gate dielectric includes a region surrounding a portion of the floating gate layer; and
in the region surrounding the portion of the first floating gate the inner layer includes a top wall and two side walls, the inner layer includes gaps between the top wall and two side walls.

27. A non-volatile memory device, comprising:
a first floating gate;
a second floating gate;
an isolation region positioned in a space between the first floating gate and the second floating gate;
a control gate layer positioned over the first floating gate and the second floating gate; and
an inter-gate dielectric comprising an ONO structure with an inner N layer and outer O layers that are positioned between the control gate layer and the first floating gate and between the control gate layer and the second floating gate, the inter-gate dielectric is positioned above the isolation region with a gap in in the inner N layer over the isolation region, the gap is sized such that the inner N layer is not positioned over any portion of the isolation region.
